(19) United States
(12) Patent Application Publication
(10) Pub. No.: US 2026/0143824 A1
(43) Pub. Date: May 21, 2026

(54) MICROELECTRONIC DEVICE FOR DETECTING ELECTROSTATIC DISCHARGE EVENTS, AND ASSOCIATED COMPONENTS, STRUCTURES, AND METHODS

(71) Applicant: Micro Technology, Inc., Boise, ID (US)

(72) Inventors: James E. Davis, Meridian, ID (US); Kenneth W. Marr, Boise, ID (US); Byung Hoon Moon, Taichung City (TW); Raj K. Bansal, Eagle, ID (US); Kevin G. Werhane, Kuna, ID (US); Souvick Mitra, Boise, ID (US); Jeffrey W. Honeycutt, Kill Devil Hills, NC (US); Rohan A. Kuriakose, Cupertino, CA (US)

(21) Appl. No.: 19/372,006

(22) Filed: Oct. 28, 2025

Related U.S. Application Data
(60) Provisional application No. 63/721,978, filed on Nov. 18, 2024.

(51) Int. Cl. H10D 89/60

(52) U.S. Cl. CPC H10D 89/819

(57) ABSTRACT

A microelectronic device includes a substrate having a bulk resistance. The microelectronic device further includes an RC timer circuit including a resistor and a capacitor positioned electrically between the substrate and the resistor at a first end of the RC timer circuit. The microelectronic device also includes a detector structure positioned electrically between the substrate and the RC timer circuit on a second end of the RC timer circuit opposite the first end.

### CROSS-REFERENCE TO RELATED APPLICATIONS

This application claims the benefit under 35 U.S.C. § 119(e) of U.S. Provisional Patent Application Ser. No. 63/721,978, filed Nov. 18, 2024, the disclosure of which is hereby incorporated herein in its entirety by this reference.

### TECHNICAL FIELD

Embodiments of the present disclosure generally relate to microelectronic devices. In particular, embodiments of the present disclosure relate to microelectronic devices configured to detect electrostatic discharge (ESD) events, and associated components, structures, and methods.

### BACKGROUND

Microelectronic devices have small paths of conductive material and microelectronic components, such as resistors, capacitors, inductors, diodes, and transistors, among other possible structures provided therein. A sudden spark or surge of static electricity into a microelectronic device is called an electrostatic discharge (ESD) strike event. An ESD strike event may damage components of the microelectronic device, such as by forming a short between one or more components, causing delamination, or damaging one or more of the microelectronic components. ESD strike event damage to the microelectronic device may cause the microelectronic device to fail prematurely. In some cases, the microelectronic device may fail immediately during testing. In other cases, the microelectronic device may be weakened, such that the microelectronic device passes initial tests but fails prematurely when in use. These cases are referred to in the industry as walking wounded.

### BRIEF DESCRIPTION OF THE DRAWINGS

FIG. 1 illustrates a lumped model of an ESD detection circuit, in accordance with embodiments of the disclosure;

FIG. 2 illustrates a simplified graph representative of the discharge of an ESD through the ESD detection circuit of FIG. 1;

FIG. 3 illustrates the ESD detection circuit of FIG. 1 including a detection device, in accordance with embodiments of the disclosure;

FIG. 4 illustrates a top-down view of a microelectronic device, in accordance with embodiments of the disclosure;

FIG. 5 illustrates a schematic view of an RC delay timer, in accordance with embodiments of the disclosure;

FIG. 6 illustrates a top-down view of an RC delay timer, in accordance with embodiments of the disclosure;

FIG. 7 illustrates an enlarged top-down view of an RC delay timer, in accordance with embodiments of the disclosure;

FIG. 8 illustrates a schematic side view of the RC delay timer of FIG. 7;

FIG. 9 illustrates an enlarged schematic view of an RC delay timer, in accordance with embodiments of the disclosure;

FIG. 10 illustrates a schematic view of an RC delay timer, in accordance with embodiments of the disclosure;

FIG. 11 illustrates a schematic view of a detector, in accordance with embodiments of the disclosure;

FIG. 12 illustrates a capacitor, in accordance with embodiments of the disclosure;

FIG. 13 illustrates a wafer, in accordance with embodiments of the disclosure;

FIG. 14 illustrates a flow chart representative of a method of detecting an ESD event, in accordance with embodiments of the disclosure; and

FIG. 15 is a schematic block diagram of an electronic system, in accordance with one or more embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refer to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co-and Ni-based alloy, an Fe- and Co-based alloy, a Co- and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

During the production of a microelectronic device, many different events can result in damage to the microelectronic device. For example, cracks may propagate through dies during a dicing operation or delamination may occur between portions of the microelectronic device during a dicing operation or a heating operation. Another event that can result in damage to the microelectronic device is an electrostatic discharge (ESD) event.

An ESD event may result in a relatively large current passing through the microelectronic device. The large current may create shorts between conductive paths within the microelectronic device and/or cause delamination between structures in the microelectronic device. In some cases, damage from an ESD event is difficult to detect, which may result in a damaged microelectronic device being sold to a consumer or installed in a product, where the microelectronic device will then fail after a short period of use or experience sporadic failures. These are referred to in the industry as “walking wounded” microelectronic devices. Improving the detection of damage from an ESD event and/or the occurrence of an ESD event with the potential to cause damage may improve the reliability of microelectronic devices produced and ultimately received by a consumer.

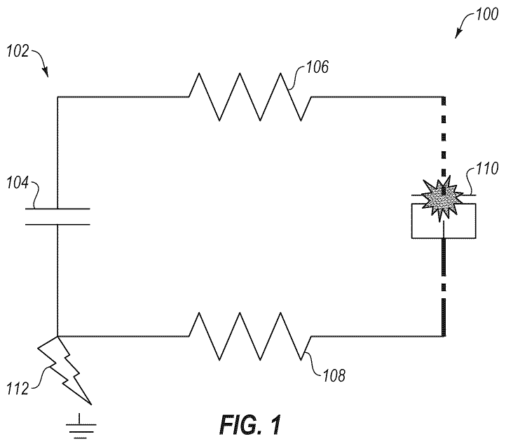

FIG. 1 illustrates a lumped model of a detection circuit 100 that may be formed within a microelectronic device. The detection circuit 100 may be configured to detect if the microelectronic device experiences an ESD event. As illustrated in FIG. 1, the detection circuit 100 includes an RC timer 102. The RC timer 102 includes a capacitor 104 and a resistor 106. The detection circuit 100 also includes a bulk resistance 108, which is representative of the resistance through the substrate of the microelectronic device equivalent with a straight line distance between opposing ends of the RC timer 102.

As discussed in further detail below, the RC timer 102 causes a delay in the passage of the current induced by an ESD event 112 through the RC timer 102, such that a voltage difference is created across a detector 110 at an end of the RC timer 102 between the RC timer 102 and the substrate of the microelectronic device. The detector 110 may include a thin dielectric structure positioned between the RC timer 102 and the bulk resistance 108 of the substrate of the microelectronic device. If the voltage created by the delay is large enough, the voltage may cause the thin dielectric structure of the detector 110 to break down, creating a short or partial short through the detector 110 that may be found or measured through a monitoring device, such as an internal monitoring circuit or an external monitoring device.

Increasing the delay through the RC timer 102 may increase the sensitivity of the detection circuit 100 to an ESD event 112 by increasing the voltage produced across the detector 110. The time delay through the RC timer 102 may be represented by a time constant (tau or τ). For example, the RC timer 102 may have a time constant within a range of from about 1 nanosecond (ns) to about 1 microsecond (μs), such as from about 5 ns to about 500 ns. The time constant of the RC timer 102 may be tuned by changing the capacitance of the capacitor 104 and the resistance of the resistor 106. For example, increasing one of the capacitance of the capacitor 104 or the resistance of the resistor 106 may increase the time constant of the RC timer 102. Similarly, decreasing one of the capacitance of the capacitor 104 or the resistance of the resistor 106 may decrease the time constant of the RC timer 102. As discussed in further detail below, the resistance of the resistor 106 may be increased by increasing a length of the path of the resistor, such as by passing the resistors through one or more structures in the associated microelectronic device and/or by serpentine line paths in the structures. The resistor 106 may be formed from conductive material, semiconductive material, or a combination thereof.

The sensitivity of the detection circuit 100 may also be increased by increasing the bulk resistance 108. As discussed above, the bulk resistance 108 is representative of the resistance through the substrate of the associated microelectronic device equivalent with a straight-line distance between opposing ends of the RC timer 102. Therefore, the bulk resistance 108 is increased by increasing the straight-line distance between the opposing ends of the RC timer 102. As illustrated in FIG. 1, the capacitor 104 forms a first end of the RC timer 102 and the detector 110 forms a second end of the RC timer 102. Therefore, the straight-line distance between the opposing ends of the RC timer 102 is the straight-line distance between the capacitor 104 and the detector 110. For example, the straight-line distance between the capacitor 104 and the detector 110 of the RC timer 102 may be within a range of from about 55 percent (%) of a length of a longest side of the associated microelectronic device to about 100 percent (%) of the length of the longest side of the associated microelectronic device. For example, the straight-line distance may be within a range of from about 500 μm to about 20,000 μm, such as within a range of from about 1,000 μm to about 15,000 μm.

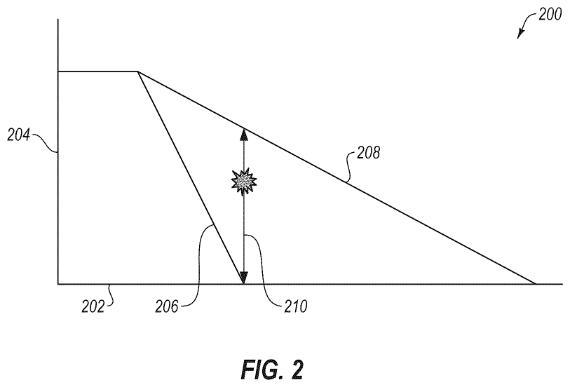

FIG. 2 illustrates a simplified graph 200 representative of a detector voltage 204 measured at the detector 110 of the detection circuit 100 over a time 202. While the lines illustrated in the simplified graph 200 are illustrated as straight lines, the actual detector voltages 204 over time 202 may be non-linear. As illustrated in FIG. 2, the same change in the detector voltage 204 manifests over different time periods at the detector 110 due to the delay from the RC timer 102. A bulk voltage 206 on a first side of the detector 110 changes at a faster rate than an RC circuit voltage 208 on a second side of the detector 110. In other words, the RC timer 102 discharges at a slower rate than the substrate of the associated microelectronic device. The difference in the rate of the voltage change results in a voltage gap 210 across the detector 110.

As discussed above, if this voltage gap 210 across the detector 110 is large enough, the voltage gap 210 may cause a dielectric material in the detector 110 to break down. The breakdown of the dielectric material in the detector 110 may result in a short or partial short between the RC timer 102 and the substrate of the associated microelectronic device. As illustrated in the graph 200, increasing the time delay of the RC timer 102 increases the voltage gap 210 between the bulk voltage 206 and the RC circuit voltage 208 resulting in greater sensitivity to an ESD event.

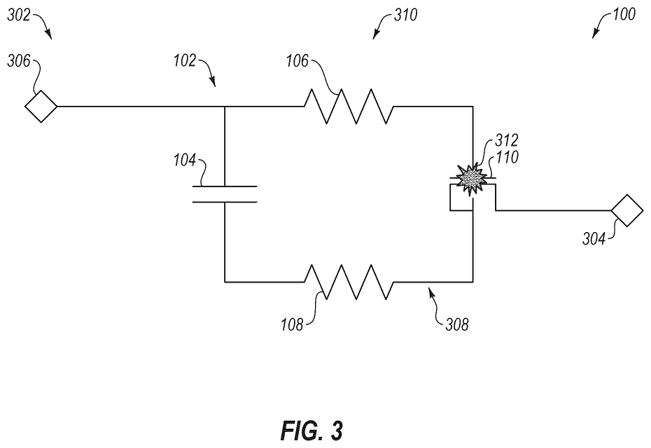

FIG. 3 illustrates the detection circuit 100 with a detection device 302 connected thereto. The detection device 302 includes a source 304, such as a voltage source, signal source, or current source, and a detector 306. In some embodiments, the detection device 302 is an external device that is connected to an associated microelectronic device during or after forming the microelectronic device. For example, the detection device 302 may be connected at different stages during the forming process, such as between steps during wafer processing, before a dicing or separation process, and/or after the dicing or separation process. Once the detection device 302 is connected, it may provide an indication if an ESD even was detected by the detector 110 prior to the detection device 302 being connected. In other embodiments, the detection device 302 is an internal circuit formed into the associated microelectronic device that may provide a signal or visual indicator if an ESD event was detected during processing.

As illustrated in FIG. 3, the source 304 of the detection device 302 is connected to the detection circuit 100 on a bulk side 308 of the detection circuit 100 and the detector 306 of the detection device 302 is connected to the detection circuit 100 on an RC timer side 310 of the detection circuit 100. The bulk side 308 of the detection circuit 100 is electrically isolated from the RC timer side 310 of the detection circuit 100 by the capacitor 104 of the RC timer 102 and the detector 110. Therefore, if the dielectric structure of the detector 110 remains intact, a signal (e.g., a voltage signal or a current signal) provided by the source 304 will not reach the detector 306. However, if an ESD event occurred that was sufficient to cause the dielectric structure of the detector 110 to break down, the damage 312 in the detector 110 may create at least a partial connection between the bulk side 308 and the RC timer side 310 of the detection circuit 100, such that the signal provided by the source 304 may reach the detector 306.

The detector 306 may be configured to provide an alert or signal if damage from an ESD event is detected. For example, the detector 306 may include a display, configured to provide visual alerts to a user. In other embodiments, the detector 306 may include lights or other visually changing elements configured to provide a visual indication of whether damage from an ESD event is detected. In some embodiments, the detector 306 is configured to generate an electrical signal that may be provided to another component, which may then generate an alert, such as an audio alert, a visual alert, or a digital alert when damage from an ESD event is detected.

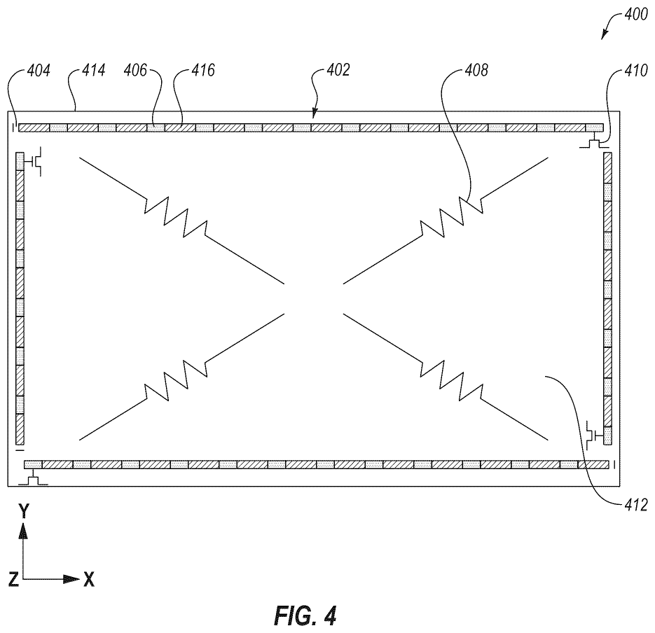

FIG. 4 illustrates a top-down view of a microelectronic device 400 including an ESD detection circuit, such as the detection circuit 100 described above with reference to FIGS. 1 and 3. The ESD detection circuit includes an RC timer 402 formed from a capacitor 404 and one or more resistors 406. As discussed above, the bulk resistance 408 of a substrate 412 of the microelectronic device 400 also forms part of the ESD detection circuit. The RC timer 402 is separated from the substrate 412 by a detector 410 at an opposite end of the RC timer 402 from the capacitor 404.

In the embodiment illustrated in FIG. 4, the RC timer 402 is arranged along outer edges 414 (e.g., an outer lateral periphery) of the microelectronic device 400. In some embodiments, the microelectronic device 400 includes a single RC timer 402 extending along one outer edge 414 of the microelectronic device 400. In other embodiments, as illustrated in FIG. 4, the microelectronic device 400 includes multiple RC timers 402 extending along multiple outer edges 414 of the microelectronic device 400. In the embodiment illustrated in FIG. 4, the microelectronic device 400 includes an RC timer 402 horizontally extending along each of the outer edges 414 of microelectronic device 400. In other embodiments, the RC timer 402 may extend through the microelectronic device 400 in different regions, such as diagonally across the microelectronic device 400; or across the microelectronic device 400, spaced a distance from one or more of the outer edges 414.

The position and orientation of the RC timer 402 in the microelectronic device 400 may be determined based on other components and structures of the microelectronic device 400, such as memory structures, microelectronic components, vias, conductive paths, and other structures present in a microelectronic device. As discussed above, increasing a length of the RC timer 402 may facilitate higher sensitivity to ESD events, at least by increasing the bulk resistance 408 associated with the ESD detection circuit including the RC timer 402. Therefore, extending the RC timer 402 along one or more outer edges 414 of the microelectronic device 400 may facilitate increasing a length of the RC timer 402 while avoiding other components and structures of the microelectronic device 400 that may be concentrated closer to a central region of the microelectronic device 400.

The resistor 406 of the RC timer 402 may be formed from multiple resistor segments 416. As described in further detail below, the resistor segments 416 may be positioned at different vertical levels (e.g., in the Z-direction) within the microelectronic device 400. The different resistor segments 416 may be configured to facilitate the detection of ESD events in different structures within the microelectronic device 400. In some cases, positioning the resistor segments 416 at the different vertical levels within the microelectronic device 400 may increase the resistance of the path through the resistor segments 416, thereby increasing the resistance of the resistor 406 and the associated time constant of the RC timer 402.

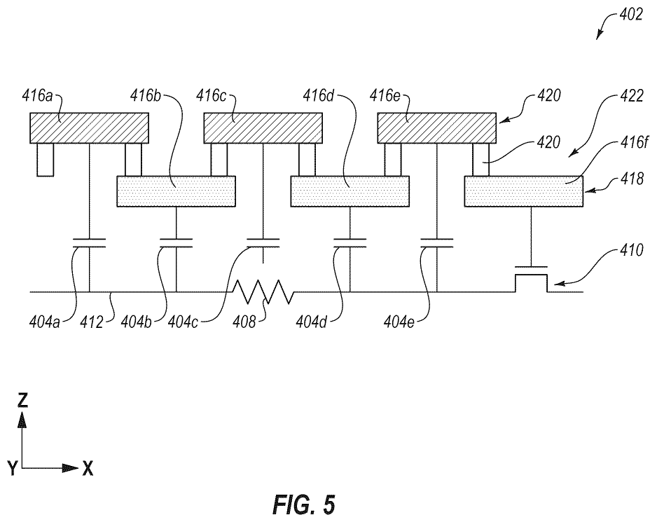

FIG. 5 illustrates a schematic view of one of the RC timers 402 in the microelectronic device 400 of FIG. 4. As noted above, the resistor 406 of the RC timer 402 is formed from multiple resistor segments 416 positioned in at least two vertically distinct structures 418, 420. The microelectronic device 400 may be formed from multiple vertically stacked structures 418, 420, 422. In the embodiment illustrated in FIG. 5, the resistor segments 416 vertically alternate between a first structure 418 and a second structure 420. The first structure 418 is vertically lower (in the Z-direction) than the second structure 420. The first structure 418 and the second structure 420 may be conductive material structures, such as metal structures or semiconductor material structures, such as source/drain-diffusion structures and polysilicon structures. The first structure 418 and the second structure 420 may be separated by one or more intermediate structures 422. The intermediate structures 422 may include insulative material structures, such as insulative structures or dielectric structures.

The resistor segments 416 may be connected through the intermediate structures 422 by conductive via structures 428 extending vertically between the resistor segments 416. As illustrated in FIG. 5, each resistor segment 416a, 416b, 416c, 416d, 416e is connected to a separate capacitor 404a, 404b, 404c, 404d, 404e. Each capacitor 404a, 404b, 404c, 404d, 404e is positioned between the respective resistor segment 416a, 416b, 416c, 416d, 416e and the substrate 412. The capacitors 404a, 404b, 404c, 404d, 404e may be positioned between the substrate 412 and the respective resistor segment 416a, 416b, 416c, 416d, 416e in the respective structures 418, 420, such that the RC timer 402 may capture ESD events in different portions of the associated microelectronic device 400.

As illustrated in FIG. 5, a final resistor segment 416f of the RC timer 402 is coupled to the detector 410, such that the detector 410 is positioned between the resistor segment 416f and the substrate 412. In some embodiments, the individual capacitors 404a, 404b, 404c, 404d, 404e have different capacitances. For example, the capacitor 404e may have a larger capacitance than the capacitor 404a. Because the capacitor 404e is positioned closer to the detector 410 than the capacitor 404a, increasing the capacitance of the capacitor 404e may accommodate the reduced resistance of the RC timer 402 between the capacitor 404e and the detector 410, where the current will pass through resistor segment 416e and resistor segment 416f in comparison with the resistance of the RC timer 402 between the capacitor 404a and the detector 410, where the current will pass through resistor segments 416a, 416b, 416c, 416d, 416e, and 416f.

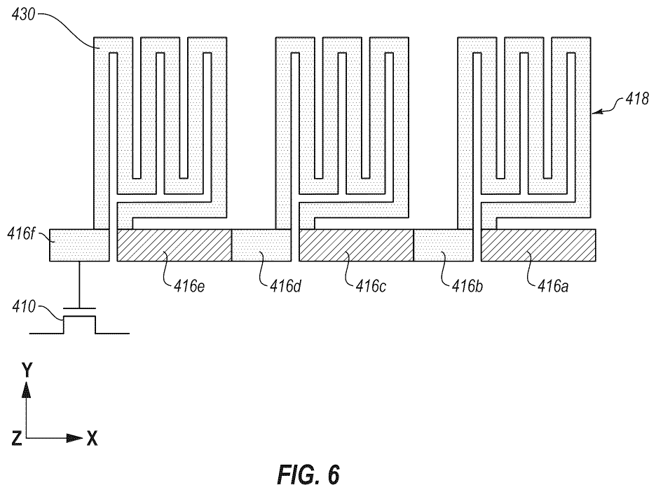

FIG. 6 illustrates a top-down view of an embodiment of the RC timer 402 illustrated in FIG. 5 at the first structure 418. In some embodiments, additional resistance may be added to the individual resistor segments 416 by increasing a path length through the resistor segments 416. In the embodiment illustrated in FIG. 6, the resistor segments 416b, 416d, 416f each include a resistor path 430 extending laterally into the first structure 418. The resistor path 430 may follow a serpentine path, as illustrated in FIG. 6. The serpentine path may facilitate increasing the length of the resistor path 430 without occupying a large area of the first structure 418. Other path designs to form a relatively long resistor path 430 within a relatively small horizontal area.

In some embodiments, each of the resistor segments 416 includes a resistor path 430 extending into the associated structures 418, 420. In other embodiments, select resistor segments 416 may include the resistor path 430 extending into the associated structures 418, 420, while other resistor segments 416 may not include an additional resistor path 430. For example, the resistor path 430 may be facilitate increasing resistance in resistor segments 416 formed in conductive structures having lower resistance than other structures in the associated microelectronic device 400, while resistor segments 416 formed in structures having higher resistance may not extend into additional resistor paths 430.

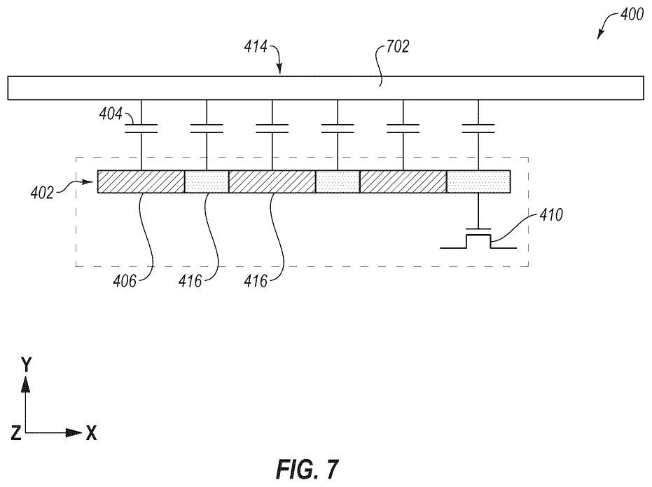

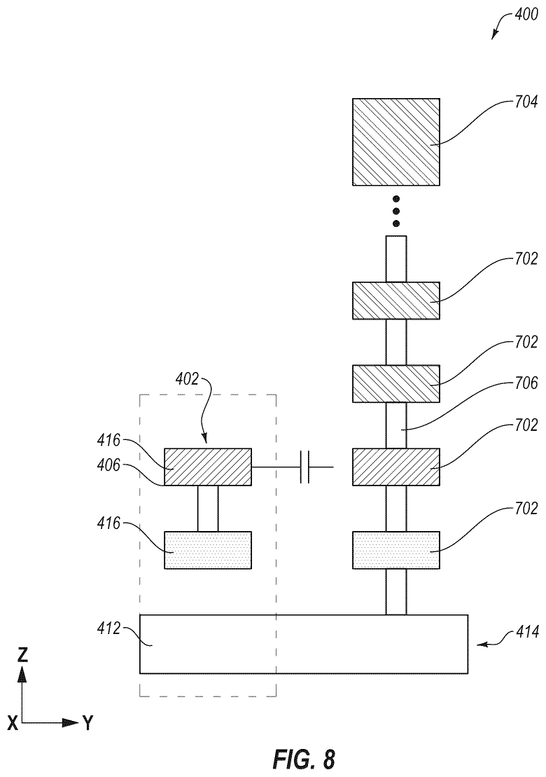

FIGS. 7 and 8 illustrate enlarged views of another embodiment of the microelectronic device 400 including the RC timer 402 and the detector 410. FIG. 7 illustrates a top-down view of a portion of the RC timer 402. FIG. 8 illustrates a side view of the RC timer 402.

In the embodiment illustrated in FIGS. 7 and 8, the capacitors 404 of the RC timer 402 are connected between the resistor segments 416 of the resistor 406 and outer conductive structures 702 formed along the outer edge 414 of the microelectronic device 400. In some embodiments, the capacitors 404 are formed from an insulative material, where the conductive structure of the resistor segments 416 and the outer conductive structures 702 act as the conductive structures surrounding the insulative structure to form the capacitors 404. In other embodiments, the capacitors 404 may be standalone structures positioned between the outer conductive structures 702 and the resistor segments 416, such that the capacitors 404 include two conductive structures on opposing sides of an insulative structure, where the two conductive structures are separate from the outer conductive structures 702 and the resistor segments 416. In other embodiments, the capacitors 404 may be formed from semiconductor materials, such as transistor devices positioned between the outer conductive structures 702 and the resistor segments 416.

In some embodiments, the outer conductive structures 702 form a die seal around the outer edges 414 of the microelectronic device 400. As illustrated in FIG. 8, the outer conductive structures 702 are vertically connected by conductive via structures 706. The outer conductive structures 702 are connected to other outer conductive structures 702 vertically higher than the RC timer 402. The conductive via structures 706 may extend up to a top structure 704 that may form an upper edge and an outer edge 414 of the microelectronic device 400, such that the top structure 704 forms an upper corner of the microelectronic device 400, sealing the upper edge and the outer edge 414 of the microelectronic device 400.

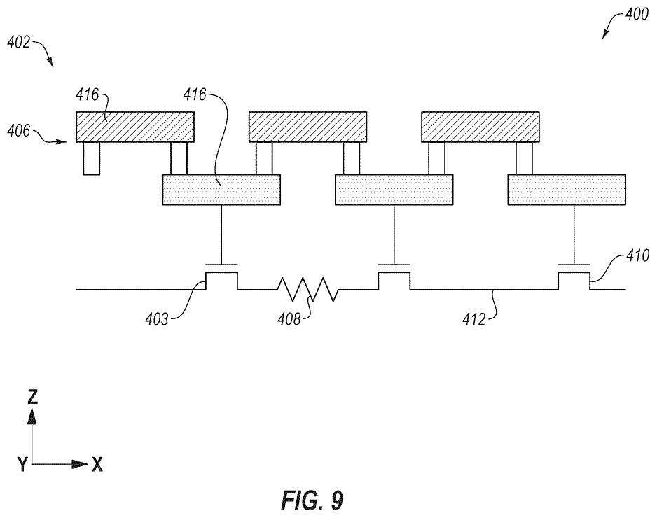

FIG. 9 illustrates a schematic view of another embodiment of the microelectronic device 400 including the RC timer 402 and the detector 410. However, the RC timer 402 is modified to employ transistors 403 in place of the capacitors 404 previously described herein. In the embodiment illustrated in FIG. 9, the transistors 403 are positioned between the substrate 412 and the resistor segments 416. The transistors 403 may, for example, be as field-effect transistors (FET) or FinFETs.

The transistors 403 and the detector 410 may have similar configurations, for example both the transistors 403 and the detector 410 may be FETs or FinFETs. However, the transistors 403 are configured to have a higher breakdown voltage than the detector 410, such that the detector 410 forms a weak point in the associated circuit. Thus, in an ESD event, the detector 410 is configured to break down before the transistors 403. For example, the transistors 403 may have a gate oxide that has a greater thickness than a gate oxide of the detector 410, such that the gate oxide of the detector 410 breaks down before the gate oxide of the transistors 403.

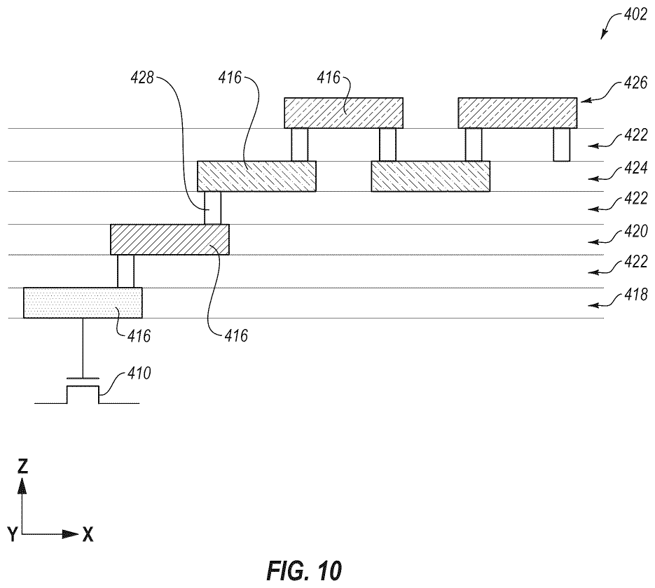

FIG. 10 illustrates a schematic view of another embodiment of the RC timer 402 in the microelectronic device 400 of FIG. 4. As noted above, the microelectronic device 400 may be formed from multiple vertically stacked structures 418, 420, 422, 424, 426. In the embodiment illustrated in FIG. 10, the resistor segments 416 are positioned in a first structure 418, a second structure 420, a third structure 424, and a fourth structure 426. The first structure 418, the second structure 420, the third structure 424, and the fourth structure 426 may be conductive material structures, such as metal structures or semiconductor material structures, such as source/drain diffusion structures and polysilicon structures. Each of the first structure 418, the second structure 420, the third structure 424, and the fourth structure 426 may be separated by one or more intermediate structures 422. The intermediate structures 422 may include insulative material structures, such as insulative structures or dielectric structures. The resistor segments 416 may be connected through the intermediate structures 422 by conductive via structures 428 extending vertically between the resistor segments 416.

The embodiment illustrated in FIG. 10 show resistor segments 416 in four vertically distinct structures 418, 420, 424, 426. In other embodiments, a microelectronic device may include resistor segments 416 in each vertically distinct conductive structure, such that the resistor 406 passes through the entire thickness of the associated microelectronic device. In some embodiments, a single microelectronic device may include different configurations of the RC timer 402. For example, the RC timer 402 along one outer edge 414 (FIG. 4) of the microelectronic device 400 (FIG. 4) may be configured to alternate between two structures 418, 420 similar to the RC timer 402 illustrated in FIG. 5, and the RC timer 402 along a second different outer edge 414 (FIG. 4) of the microelectronic device 400 (FIG. 4) may extend through all the vertically distinct conductive structures.

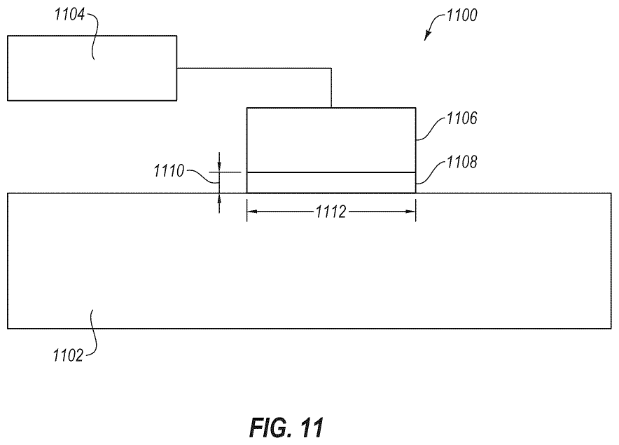

FIG. 11 illustrates a schematic view of a detector 1100, such as the detectors 110, 410 discussed above. The detector 1100 is positioned between a substrate 1102 of the microelectronic device and an RC timer 1104. The detector 1100 may include a conductive structure 1106 formed of and including one or more of conductive material and semiconductor material. The detector 1100 also includes a dielectric structure 1108 positioned between the RC timer 1104 and the substrate 1102. In the embodiment illustrated in FIG. 11, the conductive structure 1106 is positioned between the RC timer 1104 and the dielectric structure 1108, and the dielectric structure 1108 is positioned between the conductive structure 1106 and the substrate 1102.

In other embodiments, the detector 1100 may include at least two conductive structures 1106. For example, the detector 1100 may include a first conductive structure 1106 between the RC timer 1104 and the dielectric structure 1108, and a second conductive structure 1106 positioned between the substrate 1102 and the dielectric structure 1108. In other embodiments, the detector 1100 may not include the conductive structure(s) 1106. For example, the dielectric structure 1108 may be positioned directly between the RC timer 1104 and the substrate 1102, such that the RC timer 1104 and the substrate 1102 are in direct contact with the dielectric structure 1108.

The dielectric structure 1108 may be relatively thin, such that the breakdown voltage of the dielectric structure 1108 is less than any other insulative barrier between the substrate 1102 and the RC timer 1104. The dielectric structure 1108 may be formed of and include dielectric material, such as one or more of dielectric oxide material, dielectric oxycarbide material, dielectric oxynitride material, and dielectric carboxynitride material. The dielectric structure 1108 may have a thickness 1110 less than about 38 nm (about 380 Å), such as within a range of from about 2 nm (about 20 Angstrom (Å)) to about 20 nm (about 200 Å), or from about 5 nm (about 50 Å) to about 7 nm (about 70 Å). An area 1112 of the dielectric structure 1108 may be less than about 100 μm². The dielectric structure 1108 may form a weakest point in the electrical insulation between the substrate 1102 and the RC timer 1104. By making the dielectric structure 1108 the weakest point in the electrical insulation between the substrate 1102 and the RC timer 1104, an ESD event in the associated microelectronic device may break down the dielectric structure 1108 before any other insulative structure, providing a known location to check to verify if an ESD event affected the associated microelectronic device.

In some embodiments, the detector 1100 is formed as an FET, where the dielectric structure 1108 is configured as the gate oxide of the FET. Thus, when the voltage across the dielectric structure 1108 caused by the different discharge speeds is above the threshold or breakdown voltage of the dielectric structure 1108, the detector 1100 may close and send a signal to a monitoring device during the ESD event. In other embodiments, the breakdown voltage may result in damage to the dielectric structure 1108, such that a short through the detector 1100 remains between the substrate 1102 and the RC timer 1104 after the ESD event that can be detected in a subsequent monitoring step.

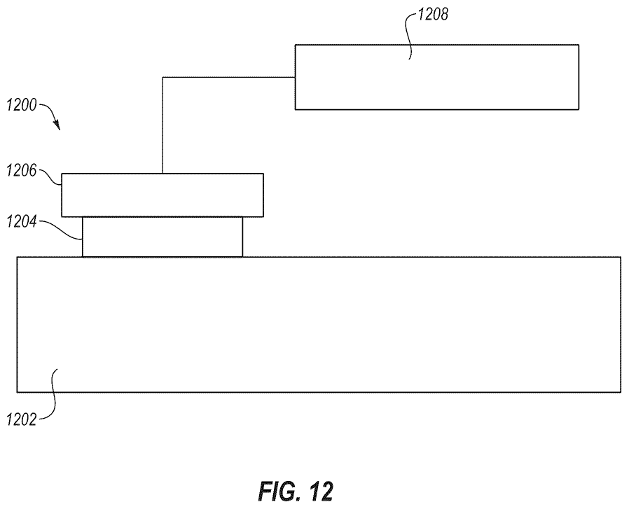

FIG. 12 illustrates a schematic view of a capacitor 1200 of an RC timer, such as the RC timers 102, 402, discussed above. The capacitor 1200 may include an insulative structure 1204 positioned between the substrate 1202 of the associated microelectronic device and a conductive structure 1206. The conductive structure 1206 may be formed from a conductive material, such as a metal material; or a semiconductor material, such as polysilicon. In other embodiments, the capacitor 1200 may include two conductive structures 1206 on opposing sides of the insulative structure 1204, such that one conductive structure 1206 is positioned between the substrate 1202 and the insulative structure 1204 and the other conductive structure 1206 is positioned between the insulative structure 1204 and a resistor structure 1208 of the associated RC timer. In another example, the capacitor 1200 may be replaced with a transistor, such as an FET or a FinFET.

As discussed above, the detector (e.g., detectors 110, 410, 1100) may be configured to have a lower breakdown voltage than any other part of the associated detector circuit. Therefore, the capacitor 1200 will have a breakdown voltage that is greater than the associated detector. For example, the insulative structure 1204 may specifically have a greater breakdown voltage than the associated detector. In some cases, the greater breakdown may be caused by the insulative structure 1204 having a greater thickness than a dielectric structure 1108 (FIG. 11) of the detector. In other cases, the insulative structure 1204 may be formed from a different material than the dielectric structure 1108 (FIG. 11) of the detector.

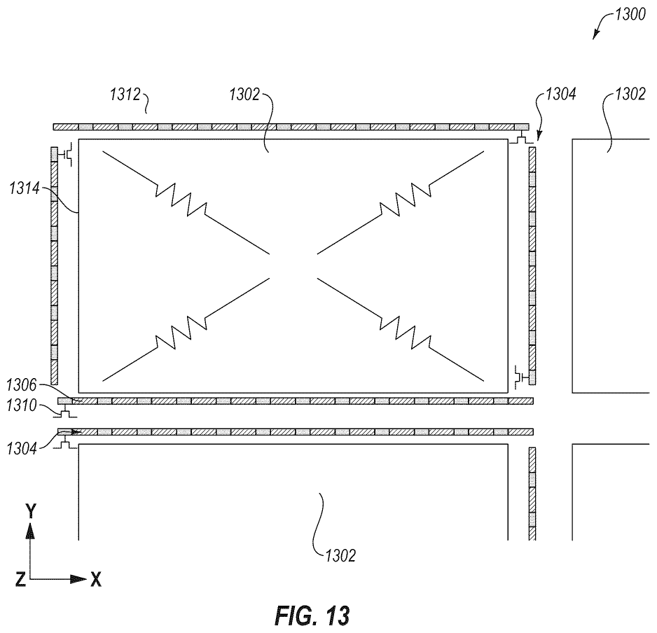

FIG. 13 illustrates an embodiment of a wafer 1300 including multiple microelectronic devices 1302 formed thereon. The microelectronic devices 1302 are separated by streets 1304. After the microelectronic devices 1302 are formed, the microelectronic devices 1302 may be separated from the detection circuit 100 through a dicing operation (e.g., a dicing saw, laser dicing, or stealth dicing). The dicing operation may remove material in the streets 1304 separating the microelectronic devices 1302 from one another.

In some embodiments, the RC timers 1306 of a detection circuit are positioned in the streets 1304 between the microelectronic devices 1302. Similar to the embodiments discussed above, the detection circuit is formed from the RC timer 1306 and a bulk resistance 1308 through a substrate 1312 (e.g., the material of the wafer 1300 or the individual microelectronic devices 1302) separated by a detector 1310. In the embodiment illustrated in FIG. 13, each street 1304 includes two RC timers 1306 each associated with a separate microelectronic device 1302 on either side of the associated street 1304. In other embodiments, each street 1304 may include a single RC timer 1306 configured to detect an ESD event in either of the microelectronic devices 1302 on either side of the associated street 1304.

As illustrated in FIG. 13, the RC timers 1306 are positioned entirely outside the outer edges 1314 of the associated microelectronic devices 1302. In some embodiments, the microelectronic devices 1302 may also include one or more RC timers 1306 positioned inward of the outer edges 1314 of the microelectronic device 1302, such as the RC timers 402 illustrated in FIG. 4. In other embodiments, the microelectronic devices 1302 may not include an RC timer (e.g., RC timer 402, 1306) inward of the outer edges 1314 thereof. Positioning the RC timers 1306 in the streets 1304 may provide additional space in the microelectronic devices 1302 for other microelectronic components, increasing a density or functionality of the microelectronic devices 1302.

As discussed above, the material in the streets 1304 is removed when separating the individual microelectronic devices 1302 from the wafer 1300. Therefore, the RC timers 1306 and detectors 1310 positioned in the streets 1304 may be removed or damaged during the dicing or separating process. An external device may be used to detect whether an ESD event is sufficient to cause damage or a breakdown in the detector 1310 before the dicing or separation process. The external device may then identify microelectronic devices 1302, where an ESD event occurred so that the identified microelectronic devices 1302 may be discarded or go through additional viability testing.

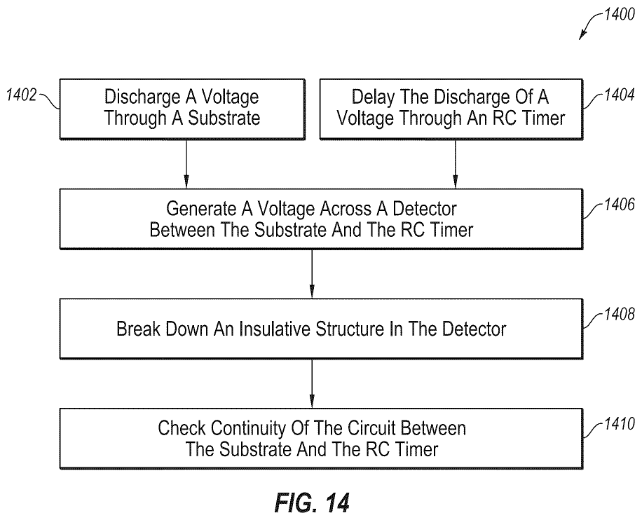

FIG. 14 illustrates a flow chart representative of a method 1400 of detecting an ESD event. The ESD event is discharged through the substrate of the microelectronic device in act 1402. As discussed above, the substrate of the microelectronic device exhibits a bulk resistance, such that the voltage generated by the ESD event is gradually discharged across the substrate. The ESD event is also discharged through an RC timer in act 1404. The discharge of the ESD event is delayed through the RC timer relative to the discharge through the substrate. The RC timer may have a time constant in a range from about 1 ns to about 1 μs. Thus, the discharge of the ESD event through the RC timer takes a greater amount of time than the discharge of the ESD event through the substrate of the microelectronic device.

A detector is positioned between the substrate of the microelectronic device and the RC timer. The delay of the discharge through the RC timer generates a voltage across the detector in act 1406. The detector includes an insulative structure positioned between the substrate of the microelectronic device and the RC timer. The voltage is generated across the insulative structure of the detector.

The insulative structure is configured to breakdown under a threshold voltage. Therefore, if the voltage generated across the insulative structure is greater than the threshold voltage the insulative structure breaks down in act 1408. The threshold voltage for breaking down the insulative structure of the detector is less than a breakdown voltage of any other insulative material positioned between the substrate of the microelectronic device and the RC timer, including the breakdown voltage of any capacitor in the RC timer. For example, the insulative structure of the detector may be configured to breakdown at a voltage less than about 75% of the breakdown voltage of any other insulative structure between the RC timer and the substrate, such as less than about 50% of the breakdown voltage of any other insulative structure between the RC timer and the substrate. Therefore, the insulative structure of the detector forms a weakest link and is configured to be the first insulative structure to breakdown in an ESD event.

The breakdown of the insulative structure of the detector may cause at least a partial short between the substrate and the RC timer. The conductivity between the substrate and the RC circuit may be measured in act 1410. As discussed above, the RC timer is separated from the substrate by insulative structures and capacitors, such that there should be no conductivity between the substrate and the RC timer unless a breakdown of an insulative structure between the RC timer and the substrate has occurred. As noted above, the insulative structure of the detector is configured to breakdown before any other insulative structure between the RC timer and the substrate. Therefore, if conductivity between the substrate and the RC timer is detected, it may be determined that an ESD event resulting in the breakdown of the insulative structure of the detector has occurred.

The conductivity measurement may be carried out by an external device configured to provide a visual or audible alert when conductivity is detected. For example, the external device may be configured to illuminate or turn off one or more lights when conductivity is detected. In another example, the external device may sound an alert, such as a beep, whistle, or other sound when conductivity is detected. In other embodiments, the external device may be connected to a user interface that may display an alert, such as one or more lights or an alert displayed on a screen. The interface may also provide an audible alert.

In some embodiments, the conductivity measurement may be carried out by an internal circuit in the associated microelectronic device. For example, the internal circuit may be configured to close or open a contact or circuit that may be checked by an external device to determine if conductivity was detected by the internal circuit. In another example, the internal circuit may be configured to store the results of the conductivity measurements in a memory device that may be accessed after the microelectronic device is formed to determine if the microelectronic device experienced an ESD event during processing.

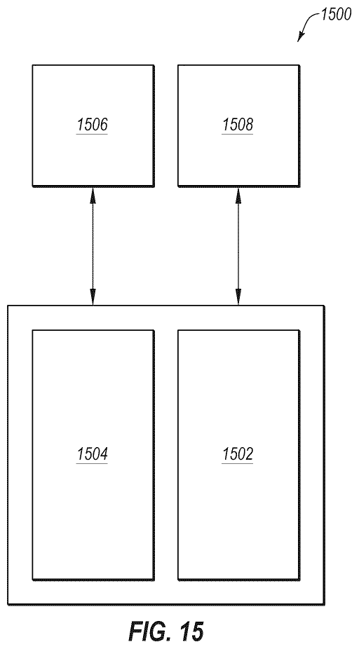

Microelectronic devices (e.g., the microelectronic devices 400, 1302) may be included in embodiments of electronic systems of the disclosure. For example, FIG. 15 is a block diagram of an electronic system 1500, in accordance with embodiments of the disclosure. The electronic system 1500 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1500 includes at least one memory device 1502. The memory device 1502 may include, for example, an embodiment of a semiconductor device package including one or more of the microelectronic devices previously described herein (e.g., the microelectronic devices 400, 1302 previously described with reference to FIGS. 4 through 13).

The electronic system 1500 may further include at least one electronic signal processor device 1504 (often referred to as a “microprocessor”). The electronic signal processor device 1504 may, optionally, include an embodiment of one or more of a microelectronic device and a microelectronic device structure previously described herein. The electronic system 1500 may further include one or more input devices 1506 for inputting information into the electronic system 1500 by a user, such as, for example, a mouse or other pointing device, a keyboard, a touchpad, a button, or a control panel. The electronic system 1500 may further include one or more output devices 1508 for outputting information (e.g., visual or audio output) to a user such as, for example, a monitor, a display, a printer, an audio output jack, a speaker, etc. In some embodiments, the input device 1506 and the output device 1508 may comprise a single touchscreen device that can be used both to input information to the electronic system 1500 and to output visual information to a user. The input device 1506 and the output device 1508 may communicate electrically with one or more of the memory device 1502 and the electronic signal processor device 1504.

Thus, embodiments of the disclosure include a microelectronic device. The microelectronic device includes a substrate having a bulk resistance. The microelectronic device further includes an RC timer circuit. The RC timer circuit includes a resistor and a capacitor positioned electrically between the substrate and the resistor at a first end of the RC timer. The microelectronic device also includes a detector structure positioned electrically between the substrate and the RC timer on a second end of the RC timer opposite the first end.

Another embodiment of the disclosure includes an electrostatic discharge (ESD) detection circuit. The ESD detection circuit includes a base material having a bulk resistance and an RC timer circuit. The RC timer circuit includes a capacitor and a resistor, the resistor having a resistance greater than the bulk resistance. The ESD detection circuit also includes an insulator positioned between the RC timer circuit and the base material.

Other embodiments of the disclosure include a method of detecting electrostatic discharge. The method includes directing an electrostatic discharge through a base material having a bulk resistance. The method further includes directing the electrostatic discharge through an RC timer circuit including a capacitor and a resistor. The method also includes generating a voltage across an insulator due to a difference in discharge speed between the base material and the RC timer. The method further includes at least partially breaking down the insulator due to the voltage across the insulator.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device, comprising:
a substrate having a bulk resistance;
an RC timer circuit comprising:
a resistor; and
a capacitor positioned electrically between the substrate and the resistor at a first end of the RC timer circuit; and
a detector structure positioned electrically between the substrate and the RC timer circuit on a second end of the RC timer circuit opposite the first end.

2. The microelectronic device of claim 1, wherein the detector structure comprises a dielectric material electrically separating the RC timer circuit from the substrate.

3. The microelectronic device of claim 2, wherein the dielectric material of the detector structure has a lower breakdown voltage than the capacitor.

4. The microelectronic device of claim 1, further comprising at least two vertically stacked structures over the substrate.

5. The microelectronic device of claim 4, wherein the resistor of the RC timer circuit comprises:
a first segment in a first structure of the at least two vertically stacked structures; and
a second segment in a second structure of the at least two vertically stacked structures.

6. The microelectronic device of claim 1, wherein the RC timer circuit has a time constant within a range of from about 1 ns to about 1 μs.

7. The microelectronic device of claim 1, wherein the resistor of the RC timer circuit has a resistance greater than the bulk resistance.

8. An electrostatic discharge detection circuit, comprising:
a base material having a bulk resistance;
an RC timer circuit comprising a capacitor and a resistor, the resistor having a resistance greater than the bulk resistance; and
an insulator positioned between the RC timer circuit and the base material.

9. The electrostatic discharge detection circuit of claim 8, wherein the RC timer circuit is electrically isolated from the base material by the capacitor and the insulator.

10. The electrostatic discharge detection circuit of claim 9, wherein the insulator has a lower breakdown voltage than the capacitor.

11. The electrostatic discharge detection circuit of claim 8, wherein the insulator has thickness less than about 380 Angstroms.

12. The electrostatic discharge detection circuit of claim 8, wherein the insulator has an area less than about 100 μm².

13. The electrostatic discharge detection circuit of claim 8, wherein the RC timer circuit is positioned within a microelectronic device.

14. The electrostatic discharge detection circuit of claim 8, wherein the RC timer circuit is positioned in streets between microelectronic devices formed in a wafer.

15. A method of detecting electrostatic discharge, the method comprising:
directing an electrostatic discharge through a base insulative material having a bulk resistance;
directing the electrostatic discharge through an RC timer circuit comprising a capacitor and a resistor;
generating a voltage across an insulator due to a difference in discharge rate between the base insulative material and the RC timer circuit; and
at least partially breaking down the insulator due to the voltage across the insulator.

16. The method of claim 15, further comprising measuring continuity between the base insulative material and the RC timer circuit.

17. The method of claim 16, further comprising generating an alert if the continuity is detected between the base insulative material and the RC timer circuit.

18. The method of claim 16, wherein measuring the continuity between the base insulative material and the RC timer circuit comprises measuring the continuity between the base insulative material and the RC timer circuit with a device external to an associated microelectronic device.

19. The method of claim 16, wherein measuring the continuity between the base insulative material and the RC timer circuit comprises measuring the continuity between the base insulative material and the RC timer circuit with a circuit within an associated microelectronic device.

20. The method of claim 15, wherein directing the electrostatic discharge through the RC timer circuit comprises directing the electrostatic discharge through the RC timer circuit at a rate slower than directing the electrostatic discharge through the base insulative material.
